(19) United States
(12) Patent Application Publication
(10) Pub. No.: US 2024/0290529 A1
(43) Pub. Date: Aug. 29, 2024

(54) COIL COMPONENT

(71) Applicant: TDK Corporation, Tokyo (JP)

(72) Inventors: Mitsuru MIURA, Tokyo (JP); Tomonaga NISHIKAWA, Tokyo (JP); Masaki ENDO, Tokyo (JP); Kazufumi SHIOIRI, Tokyo (JP); Futa GAKIYA, Tokyo (JP); Hiroki NAKAGOMI, Tokyo (JP)

(21) Appl. No.: 18/582,739

(22) Filed: Feb. 21, 2024

(30) Foreign Application Priority Data
Feb. 24, 2023 (JP) 2023-027093

(51) Int. Cl. H01F 17/00; H01F 27/29

(52) U.S. Cl. CPC H01F 17/0013; H01F 27/292

(57) ABSTRACT

Disclosed herein is a coil component that includes plural conductor layers embedded in the element body, first and second bump conductors, and first and second dummy bump conductors. Each of the conductor layers includes a coil pattern, first and second connection patterns respectively connected to the first and second bump conductors, and first and second dummy connection patterns respectively connected to the first and second dummy bump conductors. The conductor layers include first and second conductor layers. The first dummy connection pattern included in each of the first and second conductor layers has a cutout part. At least a part of the outer peripheral end of the coil pattern included in each of the first and second conductor layers is disposed within the cutout part.

### CROSS-REFERENCE TO RELATED APPLICATION

This application claims the benefit of Japanese Patent Application No. 2023-027093, filed on Feb. 24, 2023, the entire disclosure of which is incorporated by reference herein.

### BACKGROUND OF THE ART

### Field of the Art

The present disclosure relates to a coil component and, more particularly, to a two-terminal type coil component in which a single coil conductor is incorporated in an element body.

### Description of Related Art

As a two-terminal type coil component having a single coil conductor incorporated in an element body, a coil component described in JP 2022-152043A is known. In JP 2022-152043A, the surface of the coil component parallel to the stacking direction is used as a mounting surface.

In such a two-terminal type coil component, however, the coil component may rotate when being mounted on a circuit board using a solder due to the surface tension of a melted solder. To cope with this, it can be considered to provide a dummy bump conductor for preventing the rotation of the coil component, in addition to two bump conductors connected respectively to both ends of the coil conductor.

However, providing the above-mentioned dummy bump conductor reduces the inner diameter of a coil pattern, disadvantageously reducing inductance.

### SUMMARY

The present disclosure describes a technology for increasing the coil pattern inner diameter in a coil component provided with the dummy bump conductor.

A coil component according to one aspect of the present disclosure includes: an element body having a mounting surface including first, second, third, and fourth corners; a plurality of conductor layers embedded in the element body so as to be stacked in a stacking direction perpendicular to the mounting surface; first and second bump conductors respectively exposed to the first and second corners of the mounting surface; and first and second dummy bump conductors respectively exposed to the third and fourth corners of the mounting surface. Each of the plurality of conductor layers includes: a coil pattern; first and second connection patterns formed at positions respectively overlapping the first and second bump conductors as viewed in the stacking direction and respectively connected to the first and second bump conductors; and first and second dummy connection patterns formed at positions respectively overlapping the first and second dummy bump conductors as viewed in the stacking direction and respectively connected to the first and second dummy bump conductors. The coil patterns respectively included in the plurality of conductor layers are connected in series to constitute a coil conductor having a first end and a second end. The first end of the coil conductor is connected to the first connection pattern included in each of the plurality of conductor layers and the first bump conductor. The second end of the coil conductor is connected to the second connection pattern included in each of the plurality of conductor layers and the second bump conductor. The plurality of conductor layers include first and second conductor layers. The outer peripheral end of the coil pattern included in the first conductor layer and the outer peripheral end of the coil pattern included in the second conductor layer are connected to each other through a first via hole. The first dummy connection pattern included in each of the first and second conductor layers has a cutout part. At least a part of the outer peripheral end of the coil pattern included in each of the first and second conductor layers is disposed within the cutout part.

### BRIEF DESCRIPTION OF THE DRAWINGS

The above features and advantages of the present disclosure will be more apparent from the following description of certain preferred embodiments taken in conjunction with the accompanying drawings, in which:

FIGS. 1 and 2 are schematic perspective views illustrating the outer appearance of a coil component 100 according to an embodiment of the present disclosure as viewed from mutually different directions;

FIG. 3 is a schematic plan view illustrating a pattern shape of a conductor layer L1;

FIG. 4 is a schematic plan view illustrating a pattern shape of a conductor layer L2;

FIG. 5 is a schematic plan view illustrating a pattern shape of a conductor layer L3;

FIG. 6 is a schematic plan view illustrating a pattern shape of a conductor layer L4;

FIG. 7 is a schematic plan view illustrating a pattern shape of a conductor layer L5;

FIG. 8 is an enlarged view illustrating the dummy connection pattern 23 and its surroundings;

FIG. 9 is an enlarged view illustrating the dummy connection pattern 33 and its surroundings;

FIG. 10 is an enlarged view illustrating the dummy connection pattern 24 and its surroundings;

FIG. 11 is an enlarged view illustrating the connection pattern 21 and its surroundings;

FIG. 12 is an enlarged view illustrating the connection pattern 22 and its surroundings;

FIG. 13 is a YZ cross-sectional view of the coil component 100;

FIG. 14 is a YZ cross-sectional view of a coil component according to a modification;

FIG. 15 is a schematic partial plan view illustrating a circuit board 200 mounting thereon the coil component 100; and

FIG. 16 is a partial cross-sectional view of the coil component 100 mounted on the circuit board 200.

### DETAILED DESCRIPTION OF THE EMBODIMENTS

Preferred embodiments of the present disclosure will be explained below in detail with reference to the accompanying drawings.

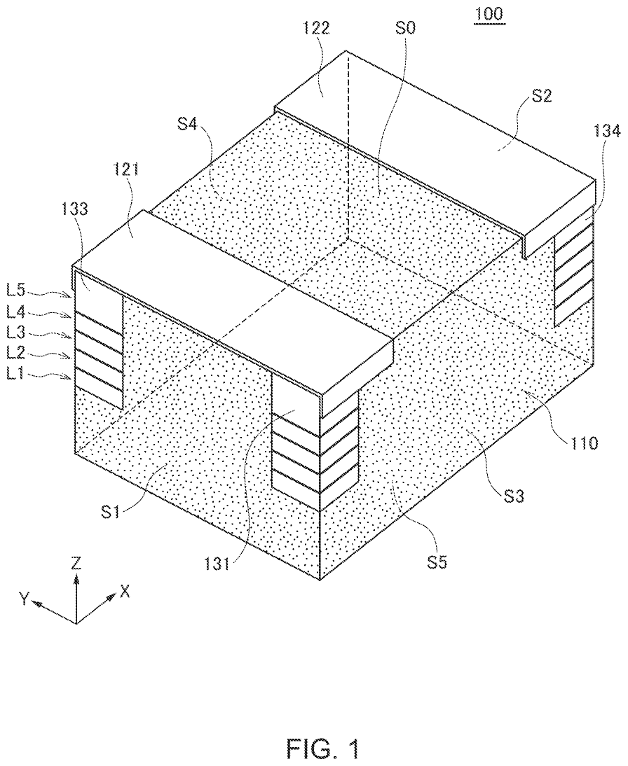

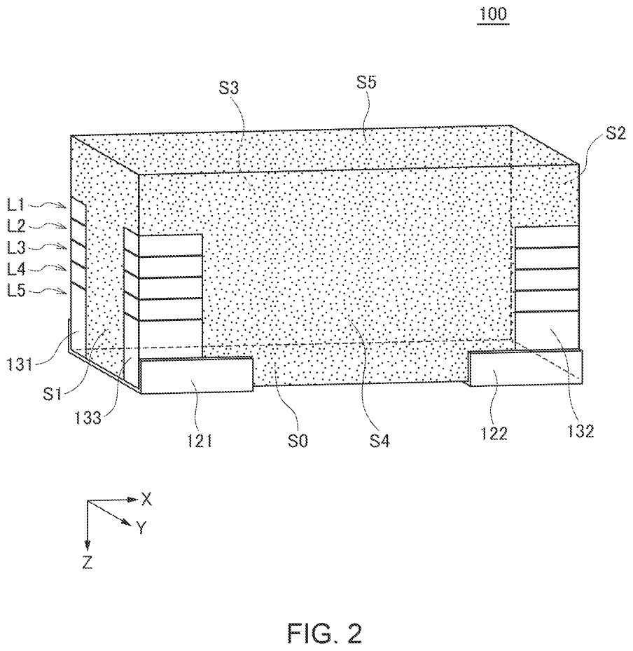

FIGS. 1 and 2 are schematic perspective views illustrating the outer appearance of a coil component 100 according to an embodiment of the present disclosure as viewed from mutually different directions.

As illustrated in FIGS. 1 and 2, the coil component 100 according to the present embodiment has an element body 110 and a pair of conductive resin layers 121 and 122 covering the surfaces of the element body 110. The element body 110 is made of a composite magnetic material containing magnetic filler made of a metal magnetic body and a resin binder and embeds therein a coil conductor to be described later. The surfaces of the element body 110 include a mounting surface S0 and an upper surface S5 which constitute the XY plane, side surfaces S1 and S2 which constitute the YZ plane, and side surfaces S3 and S4 which constitute the XZ plane. In actual use, the coil component 100 is mounted such that the mounting surface S0 faces the surface of the circuit board. As described above, the side surfaces S1 to S4 are perpendicular to the mounting surface S0, the side surfaces S1 and S2 are parallel to each other, and the side surfaces S3 and S4 are parallel to each other. The side surfaces S1 and S2 are perpendicular to the side surfaces S3 and S4. When viewed in the Z-direction (stacking direction), the element body 110 is long in the X-direction and short in the Y-direction.

Bump conductors 131, 132 and dummy bump conductors 133, 134 are exposed to the surfaces of the element body 110. The bump conductor 131 is connected to one end of the coil conductor embedded in the element body 110, and the bump conductor 132 is connected to the other end of the coil conductor embedded in the element body 110. The dummy bump conductors 133 and 134 are not connected directly to the coil conductor but connected respectively to the bump conductors 131 and 132 through the respective conductive resin layers 121 and 122. The bump conductors 131, 132 and dummy bump conductors 133, 134 are each exposed to three surfaces of the element body 110. Specifically, the bump conductor 131 is exposed to the mounting surface S0 and side surfaces S1 and S3, the bump conductor 132 is exposed to the mounting surface S0 and side surfaces S2 and S4, the dummy bump conductor 133 is exposed to the mounting surface S0 and side surfaces S1 and S4, and the dummy bump conductor 134 is exposed to the mounting surface S0 and side surfaces S2 and S3. That is, the bump conductor 131 and 132 are diagonally arranged, and the dummy bump conductors 133 and 134 are diagonally arranged.

The conductive resin layers 121 and 122 are each made of a conductive material containing metal powder and a resin binder, such as silver paste and are provided at least on the mounting surface S0 of the element body 110. The conductive resin layer 121 connects the bump conductor 131 and the dummy bump conductor 133, and the conductive resin layer 122 connects the bump conductor 132 and the dummy bump conductor 134. In the example illustrated in FIGS. 1 and 2, the conductive resin layers 121 and 122 each partly cover the side surfaces S3 and S4 of the element body 110; however, a side surface part of each of the bump conductors 131, 132 and dummy bump conductors 133, 134 that are exposed to the side surfaces S1, S2, S3, and S4 of the element body 110 are at least partly not covered with the conductive resin layer 121 or 122. The side surface part of the bump conductor 131 refers to an exposed part to the side surfaces S1 and S3, the side surface part of the bump conductor 132 refers to an exposed part to the side surfaces S2 and S4, the side surface part of the dummy bump conductor 133 refers to an exposed part to the side surfaces S1 and S4, and the side surface part of the dummy bump conductor 134 refers to an exposed part to the side surfaces S2 and S3.

In the example illustrated in FIGS. 1 and 2, the conductive resin layer 121 does not cover a part of each of the bump conductor 131 and dummy bump conductor 133 that is exposed to the side surface S1. Similarly, the conductive resin layer 122 does not cover a part of each of the bump conductor 132 and dummy bump conductor 134 that is exposed to the side surface S2. Thus, it is possible to sufficiently ensure the area of the side surface part of each of the bump conductors 131, 132 and dummy bump conductors 133, 134 that is exposed without being covered with the conductive resin layer 121 or 122. In this case, the conductive resin layers 121 and 122 respectively constitute so-called L-shape electrodes on the bump conductors 131, 132 and dummy bump conductors 133, 134.

Alternatively, a part of each of the bump conductor 131 and dummy bump conductor 133 that is exposed to the side surface S1 may be covered with the conductive resin layer 121, and a part of each of the bump conductor 132 and dummy bump conductor 134 that is exposed to the side surface S2 may be covered with the conductive resin layer 122. In this case, the thickness of the conductive resin layer 121 may be larger at the portion covering the bump conductor 131 and dummy bump conductor 133 that are exposed respectively to the side surfaces S3 and S4 than at the portion covering the bump conductor 131 and dummy bump conductor 133 that are exposed to the side surface S1. Similarly, the thickness of the conductive resin layer 122 may be larger at the portion covering the bump conductor 132 and dummy bump conductor 134 that are exposed respectively to the side surfaces S3 and S4 than at the portion covering the bump conductor 132 and dummy bump conductor 134 that are exposed to the side surface S2. This makes rotational deviation of the mounting position to be described later unlikely to occur.

The element body 110 embeds therein, for example, five conductor layers L1 to L5 stacked in the Z-direction (stacking direction) perpendicular to the mounting surface S0, and a coil conductor is constituted by the conductor layers L1 to L5. The conductor layers L1 to L5 are each made of copper (Cu) or the like and each have a resistance lower than at least the resistance of each of the conductive resin layers 121 and 122.

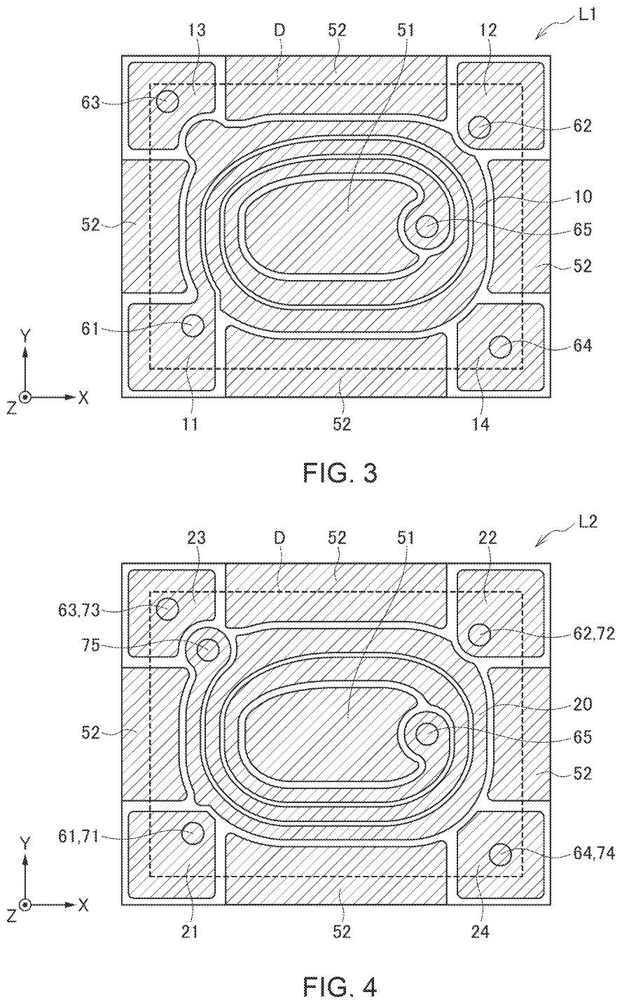

FIGS. 3 to 7 are schematic plan views illustrating pattern shapes of the respective conductor layers L1 to L5. The patterns illustrated in FIGS. 3 to 6 are those formed during manufacturing of the coil component 100 according to the present embodiment, and a sacrificial pattern 51 positioned at the inner diameter area surrounded by the coil pattern and a sacrificial pattern 52 positioned at the outside area of the coil pattern are finally removed. A space formed by removal of the sacrificial patterns 51 and 52 is filled with the composite magnetic material forming the element body 110. The dashed line D shown in FIGS. 3 to 6 is a dicing line for singulation. Thus, the dashed line D corresponds to the side surfaces S1 to S4 of the element body 110.

As illustrated in FIG. 3, the conductor layer L1 has a coil pattern 10, connection patterns 11 and 12, and dummy connection patterns 13 and 14. The outer peripheral end of the coil pattern 10 is connected to the connection pattern 11. The connection pattern 12 and dummy connection patterns 13 and 14 are not connected to the coil pattern 10 within the surface of the conductor layer L1 and independent of one another therewithin.

As illustrated in FIG. 4, the conductor layer L2 has a coil pattern 20, connection patterns 21 and 22, and dummy connection patterns 23 and 24. The inner peripheral end of the coil pattern 20 is connected to the inner peripheral end of the coil pattern 10 through a via hole 65. The connection patterns 21, 22 and dummy connection patterns 23, 24 are connected respectively to the connection patterns 11, 12 and dummy connection patterns 13, 14 through corresponding via holes 61 to 64 but not connected to the coil pattern 20 within the surface of the conductor layer L2 and independent of one another therewithin.

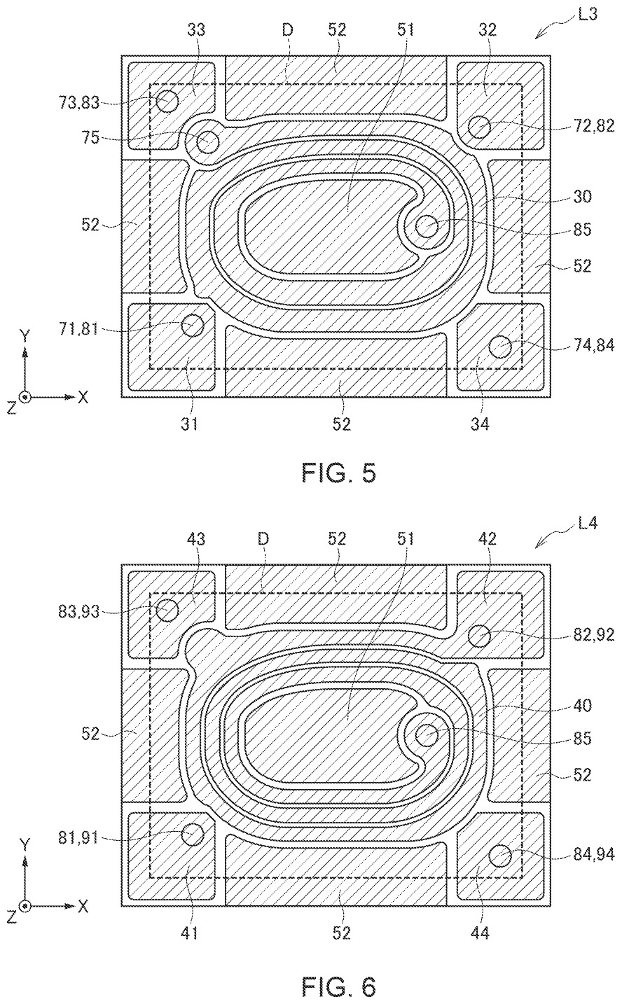

As illustrated in FIG. 5, the conductor layer L3 has a coil pattern 30, connection patterns 31 and 32, and dummy connection patterns 33 and 34. The outer peripheral end of the coil pattern 30 is connected to the outer peripheral end of the coil pattern 20 through a via hole 75. The connection patterns 31, 32 and dummy connection patterns 33, 34 are connected respectively to the connection patterns 21, 22 and dummy connection patterns 23, 24 through corresponding via holes 71 to 74 but not connected to the coil pattern 30 within the surface of the conductor layer L3 and independent of one another therewithin.

As illustrated in FIG. 6, the conductor layer L4 has a coil pattern 40, connection patterns 41 and 42, and dummy connection patterns 43 and 44. The inner peripheral end of the coil pattern 40 is connected to the inner peripheral end of the coil pattern 30 through a via hole 85. The outer peripheral end of the coil pattern 40 is connected to the connection pattern 42. The connection pattern 41 and dummy connection patterns 43 and 44 are not connected to the coil pattern 40 within the surface of the conductor layer L4 and independent of one another therewithin. The connection patterns 41, 42 and dummy connection patterns 43, 44 are connected respectively to the connection patterns 31, 32 and dummy connection patterns 33, 34 through corresponding via holes 81 to 84.

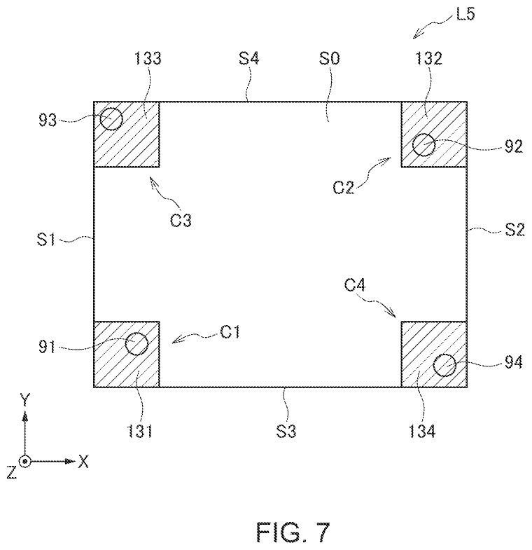

As illustrated in FIG. 7, the conductor layer L5 has bump conductors 131, 132 and dummy bump conductors 133, 134. When viewed in the Z-direction (stacking direction), the bump conductor 131 overlaps the connection patterns 11, 21, 31, and 41, the bump conductor 132 overlaps the connection patterns 12, 22, 32, and 42, the dummy bump conductor 133 overlaps the dummy connection patterns 13, 23, 33, and 43, and the dummy bump conductor 134 overlaps the dummy connection patterns 14, 24, 34, and 44. The bump conductors 131, 132 and dummy bump conductors 133, 134 are connected respectively to the connection patterns 41, 42 and dummy connection patterns 43, 44 through corresponding via holes 91 to 94. The conductor layer L5 is exposed to the mounting surface S0, and the bump conductors 131, 132 and dummy bump conductors 133, 134 are exposed respectively to corners C1 to C4 of the mounting surface S0. The corner C1 is formed by the side surfaces S1 and S3, the corner C2 is formed by the side surfaces S2 and S4, the corner C3 is formed by the side surfaces S1 and S4, and the corner C4 is formed by the side surfaces S2 and S3.

With this configuration, one end and the other end of the coil conductor including the series-connected coil patterns 10, 20, 30, and 40 are connected respectively to the bump conductors 131 and 132. Further, as illustrated in FIGS. 1 and 2, the bump conductor 131 and dummy bump conductor 133 are connected to each other through the conductive resin layer 121, and the bump conductor 132 and dummy bump conductor 134 are connected to each other through the conductive resin layer 122. As a result, although the coil component 100 according to the present embodiment is a two-terminal type coil component in which a single coil conductor is incorporated in the element body 110, it can have a terminal structure comparable to a four-terminal type coil component due to the presence of the two dummy bump conductors 133 and 134.

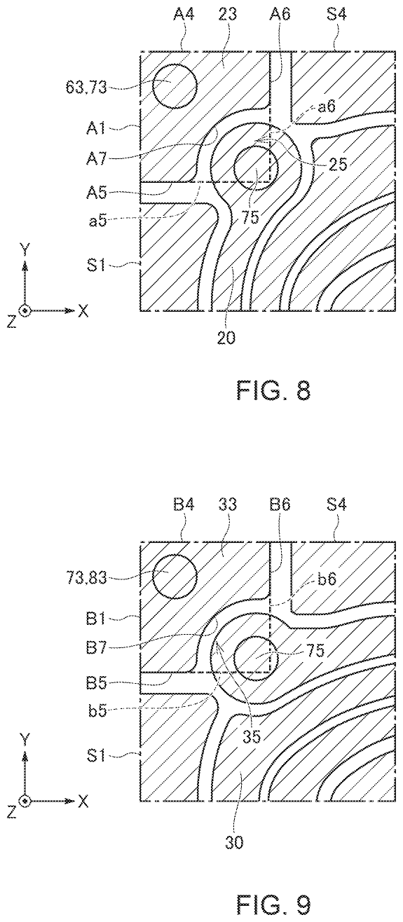

FIG. 8 is an enlarged view illustrating the dummy connection pattern 23 and its surroundings, and FIG. 9 is an enlarged view illustrating the dummy connection pattern 33 and its surroundings.

As illustrated in FIG. 8, the dummy connection pattern 23 provided in the conductor layer L2 is not simply rectangular but has a cutout part 25. More specifically, in a plan view (as viewed in the Z-direction), the dummy connection pattern 23 has a side A1 extending along the side surface S1, a side A4 extending along the side surface S4, a side A5 extending in the X-direction within the element body 110 and having one end connected to the side A1, a side A6 extending in the Y-direction within the element body 110 and having one end connected to the side A4, and a side A7 positioned within the element body 110 and having both ends connected respectively to the A5 and A6. The area surrounded by a virtual line a5 obtained by extending the side A5, a virtual line a6 obtained by extending the side A6, and the side A7 is the cutout part 25. That is, the area of the dummy connection pattern 23 is smaller by the area of the cutout part 25 than that when the dummy connection pattern 23 is simply rectangular. The side A7 is curved so as to form a concave part, whereby the area of the cutout part 25 is larger than that when it is triangular.

A part of the outer peripheral end of the coil pattern 20 is disposed within the cutout part 25. In the example illustrated in FIG. 8, a part of the via hole 75 is also disposed within the cutout part 25. Thus, as compared with when the dummy connection pattern 23 is simply rectangular, the outer peripheral end of the coil pattern 20 and the via hole 75 can be brought close to the side surfaces S1 and S4 of the element body 110, resulting in an increase in the outer and inner diameters of the coil pattern 20. Further, the outer peripheral end of the coil pattern 20 partly has a convex shape along the concave-curved side A7, meaning that, at a portion along the side A7, the distance between the coil pattern 20 and the dummy connection pattern 23 is almost constant.

The same applies to the outer peripheral end of the dummy connection pattern 33 and coil pattern 30 which are provided in the conductor layer L3. That is, the dummy connection pattern 33 is not simply rectangular but has a cutout part 35. More specifically, in a plan view (as viewed in the Z-direction), the dummy connection pattern 33 has a side B1 extending along the side surface S1, a side B4 extending along the side surface S4, a side B5 extending in the X-direction within the element body 110 and having one end connected to the side B1, a side B6 extending in the Y-direction within the element body 110 and having one end connected to the side B4, and a side B7 positioned within the element body 110 and having both ends connected respectively to the B5 and B6. The area surrounded by a virtual line b5 obtained by extending the side B5, a virtual line b6 obtained by extending the side B6, and the side B7 is the cutout part 35. That is, the area of the dummy connection pattern 33 is smaller by the area of the cutout part 35 than that when the dummy connection pattern 33 is simply rectangular. The side B7 is curved so as to form a concave part, whereby the area of the cutout part 35 is larger than that when the cutout part 35 is triangular.

A part of the outer peripheral end of the coil pattern 30 is disposed within the cutout part 35. In the example illustrated in FIG. 9, a part of the via hole 75 is also disposed within the cutout part 35. Thus, as compared with when the dummy connection pattern 33 is simply rectangular, the outer peripheral end of the coil pattern 30 and via hole 75 can be brought close to the side surfaces S1 and S4 of the element body 110, resulting in an increase in the outer and inner diameters of the coil pattern 30. Further, the outer peripheral end of the coil pattern 30 partly has a convex shape along the concave-curved side B7, meaning that, at a portion along the side B7, the distance between the coil pattern 30 and the dummy connection pattern 33 is almost constant.

On the other hand, as illustrated in FIGS. 3 and 4, the via hole 65 connecting the inner peripheral end of the coil pattern 10 and the inner peripheral end of the coil pattern 20 is disposed at substantially the center portion in the Y-direction and offset to the side surface 2 side in the X-direction. Similarly, as illustrated in FIGS. 5 and 6, the via hole 85 connecting the inner peripheral end of the coil pattern 30 and the inner peripheral end of the coil pattern 40 is disposed at substantially the center portion in the Y-direction and offset to the side surface 2 side in the X-direction. That is, the X-direction positions of the respective via holes 65 and 85 are closer to the bump conductor 132 and dummy bump conductor 134 than to the bump conductor 131 and dummy bump conductor 133.

As described above, the X-direction position of the via hole 75 connecting the outer peripheral ends of the coil pattern is offset to the side surface S1 side, and the X-direction positions of the via holes 65 and 85 connecting the inner peripheral ends of the coil patterns are offset to the side surface S2 side. This can increase the outer and inner diameters of each of the coil patterns 10, 20, 30, and 40.

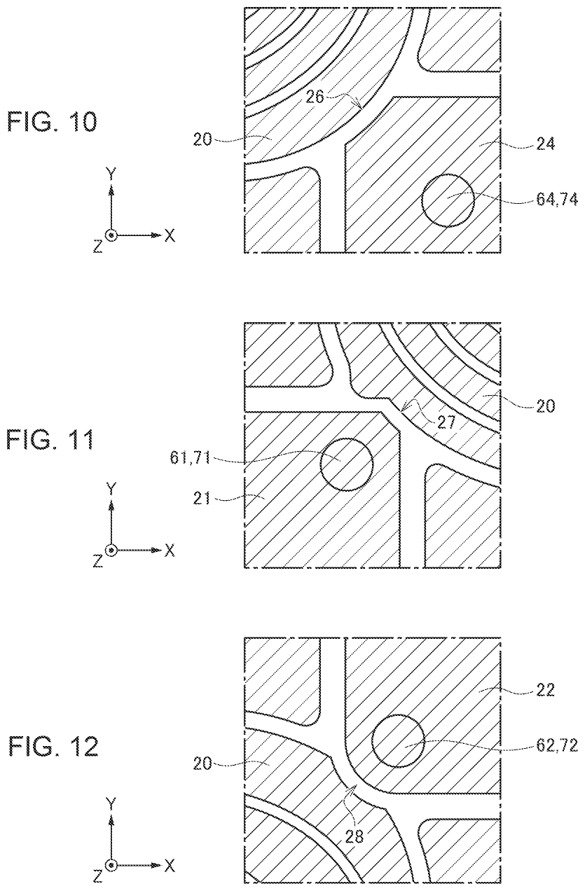

Further, as illustrated in FIG. 10, the dummy connection pattern 24 has a cutout part 26; however, the cutout part 26 is smaller in size than the cutout part 25. Accordingly, the dummy connection pattern 24 is larger in area than the dummy connection pattern 23. Although a part of the coil pattern 20 extends along the cutout part 26 of the dummy connection pattern 24, the pattern width of the coil pattern 20 is not reduced at this portion. This prevents the resistance value of the coil pattern 20 from increasing at this portion. The same applies to the dummy connection patterns 14, 34, 44 included respectively in the conductor layers L1, L3, and L4.

As illustrated in FIGS. 11 and 12, the connection patterns 21 and 22 have cutout parts 27 and 28, respectively; however, the cutout parts 27 and 28 are smaller in size than the cutout part 26. Accordingly, the connection patterns 21 and 22 are larger in area than the dummy connection pattern 24. A part of the coil pattern 20 extends along the cutout parts 27 and 28 of the connection patterns 21 and 22, and the pattern width of the coil pattern 20 is locally reduced at these portions. This can sufficiently ensure the areas of the connection patterns 21 and 22. The same applies to the connection patterns 12, 31, 32, and 41 included respectively in the conductor layers L1, L3, and L4.

Further, as illustrated in FIGS. 3 to 7, the shortest distance between the via holes 61, 71, 81, and 91 connecting the connection patterns 11, 21, 31, 41 and the bump conductor 131 and the side surfaces S1 and S3 of the element body 110 and the shortest distance between the via holes 62, 72, 82, and 92 connecting the connection patterns 12, 22, 32, 42 and the bump conductor 132 and the side surfaces S2 and S4 of the element body 110 are larger than the shortest distance between the via holes 63, 73, 83, and 93 connecting the dummy connection patterns 13, 23, 33, 43 and the dummy bump conductor 133 and the side surfaces S1 and S4 of the element body 110 and the shortest distance between the via holes 64, 74, 84, and 94 connecting the dummy connection patterns 14, 24, 34, 44 and the dummy bump conductor 134 and the side surfaces S2 and S3 of the element body 110. This is because dicing displacement may occur when the plurality of coil component 100 are obtained through a singulation process. That is, the via holes connected to the bump conductors 131 and 132 are each disposed as inside as possible so as not to be cut when dicing displacement occurs. On the other hand, the via holes connected to the dummy bump conductors 133 and 134 are each disposed at a position where design margin is ensured as much as possible. Therefore, when dicing displacement occurs, the via holes connected to the dummy bump conductors 133 and 134 may be partly cut to expose a via conductor to the side surfaces S1 to S4 of the element body 110.

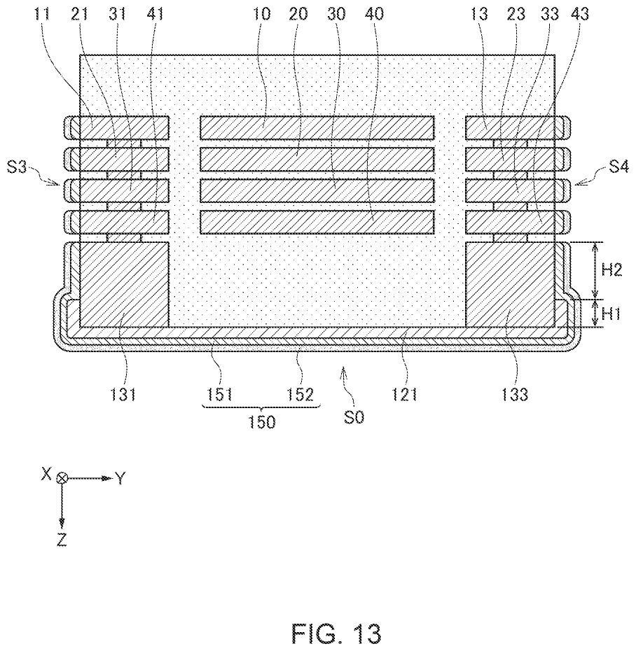

FIG. 13 is a YZ cross-sectional view of the coil component 100 according to the present embodiment.

As illustrated in FIG. 13, the surfaces of the respective conductor layers L1 to L5 exposed from the element body 110 and the surfaces of the respective conductive resin layers 121 and 122 are covered with a surface treatment layer 150. The surface treatment layer 150 acts to enhance wettability to solder and is composed of, for example, an Ni film 151 and an Sn film 152. The surface treatment layer 150 is partly formed on the side surface of each of the bump conductors 131, 132 and dummy bump conductors 133, 134 directly, not through the conductive resin layer 121 or 122. As a result, as compared with when the surface of each of the bump conductors 131, 132 and dummy bump conductors 133, 134 is completely covered with the conductive resin layers 121 and 122 having a comparatively high resistance, the resistance value between the surface treatment layer 150 and each of the bump conductors 131, 132 and dummy bump conductors 133, 134 is reduced. On the other hand, the conductive resin layers 121 and 122 are high in flexibility and thus act to enhance stress relaxation resistance.

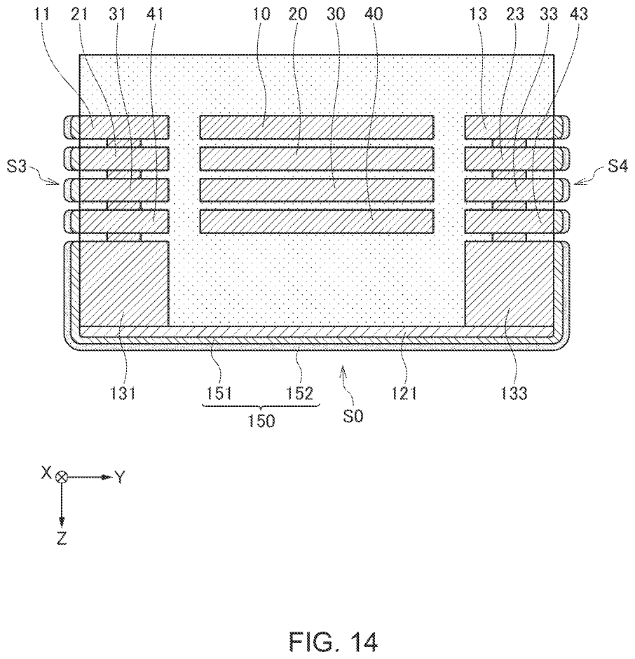

Further, in the present embodiment, the conductive resin layers 121 and 122 each partly go around to the side surfaces S3 and S4 of the element body 110 and, accordingly, the side surface of each of the bump conductors 131, 132 and dummy bump conductors 133, 134 is partly covered with the conductive resin layer 121 or 122. With the above structure, stress relaxation resistance is further enhanced. Even in this case, a height H1 in the Z-direction of a part of the side surface that is covered with the conductive resin layer 121 or 122 is preferably smaller than a height H2 in the Z-direction of a part of the surface that is not covered therewith. This sufficiently ensures contact areas between the bump conductors 131, 132 and dummy bump conductors 133, 134 and the surface treatment layer 150. However, in the present invention, it is not essential that the conductive resin layers 121 and 122 each partly go around the side surfaces S3 and S4, but as illustrated in the YZ cross-sectional view of FIG. 14, the conductive resin layers 121 and 122 may each be formed only on the mounting surface S0 of the element body 110. This further reduces a connection resistance.

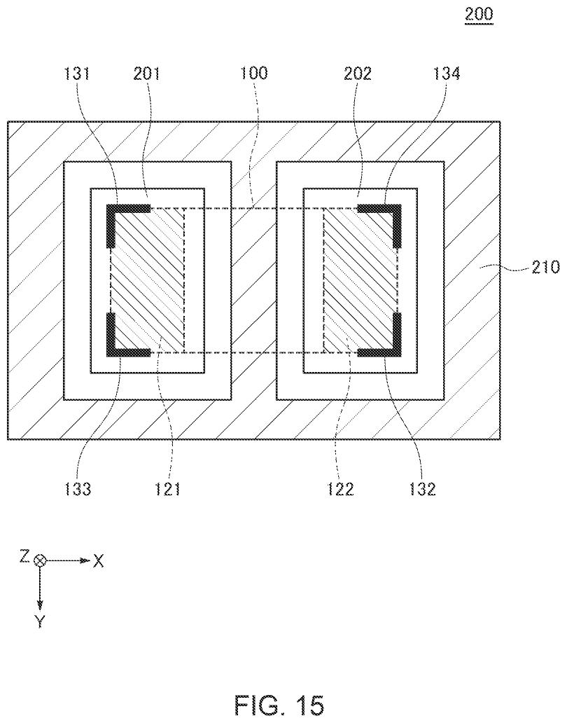

FIG. 15 is a schematic partial plan view illustrating a circuit board 200 mounting thereon the coil component 100 according to the present embodiment.

In the circuit board 200 illustrated in FIG. 15, a large part of the XY surface as the main surface is covered with a solder resist 210, and a pair of land patterns 201 and 202 are exposed from the solder resist 210. The land patterns 201 and 202 respectively face the conductive resin layers 121 and 122 of the coil component 100. In FIG. 15, the mounting position of the coil component 100 is denoted by a dashed line.

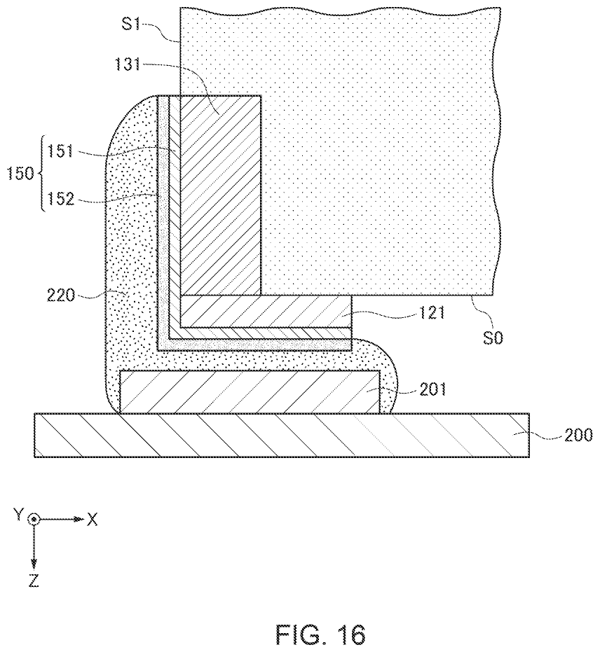

As illustrated in FIG. 16 that is a partial cross-sectional view, in a state where the coil component 100 according to the present embodiment is mounted on the circuit board 200 having the above structure, the land pattern 201 and the bump conductor 131 are connected to each other through a solder 220. In a not-illustrated another cross section, the land pattern 202 and the bump conductor 132 are connected to each other through the solder 220. On the mounting surface S0 side of the element body 110, the solder 220 and the bump conductor 131 are connected to each other through the conductive resin layer 121, while on the side surface S1 side of the element body 110, the solder 220 and the bump conductor 131 are directly connected to each other, not through the conductive resin layer 121. This reduces the connection resistance between the solder 220 and the bump conductor 131. In addition, the conductive resin layer 121 having high flexibility is present on the mounting surface S0 side of the element body 110, so that even when stress is applied to the coil component 100 from the circuit board 200 side, it is relaxed by the conductive resin layer 121, thus increasing mounting reliability.

Further, the four terminal electrodes of the bump conductors 131, 132 and dummy bump conductors 133, 134 are exposed to the side surfaces Si to S4 of the element body 110, and thus the fillet of the solder 220 is formed at the four corners denoted by thick lines in FIG. 15. This can obtain mounting characteristics equivalent to those of a four-terminal type coil component, making translational deviation and rotational deviation of the mounting position unlikely to occur. The effect of preventing the rotational deviation is enhanced when the planar shape of each of the bump conductors 131, 132 and dummy bump conductors 133, 134 exposed to the mounting surface S0 is square. It is because when the planar shape of each of the bump conductors 131, 132 and dummy bump conductors 133, 134 exposed to the mounting surface S0 is square, the Y-direction width of the bump conductor 131 exposed to the side surface S1 and the X-direction width thereof exposed to the side surface S3 are equal to each other, the Y-direction width of the bump conductor 132 exposed to the side surface S2 and the X-direction width thereof exposed to the side surface S4 are equal to each other, the Y-direction width of the dummy bump conductor 133 exposed to the side surface S1 and the X-direction width thereof exposed to the side surface S4 are equal to each other, and the Y-direction width of the dummy bump conductor 134 exposed to the side surface S2 and the X-direction width thereof exposed to the side surface S3 are equal to each other.

The connection patterns 11 to 14, 21 to 24, 31 to 34, and 41 to 44 are also exposed to the side surfaces S1 to S4 of the element body 110; however, they are separated on the side surfaces S1 to S4 of the element body 110 through interlayer insulating films, so that the fillet of the solder 220 is unlikely to be formed on the connection patterns 11 to 14, 21 to 24, 31 to 34, and 41 to 44 exposed to the side surfaces S1 to S4. This prevents the height of the fillet of the solder 220 from increasing unnecessarily, so that high density mounting is not hindered. However, the fillet of the solder 220 may be formed on the connection patterns 11 to 14, 21 to 24, 31 to 34, and 41 to 44 exposed to the side surfaces S1 to S4 by deformation of the connection pattern caused in a singulation process or the presence of the via conductors exposed to the side surfaces S1 to S4 of the element body 110.

As described above, in the coil component according to the present embodiment, the outer peripheral ends of the coil patterns 20 and 30 are respectively disposed within the cutout parts 25 and 35 of the dummy connection patterns 23 and 33 so as to protrude into the areas of the dummy connection patterns 23 and 33, respectively, thus allowing an increase in the outer and inner diameters of each of the coil patterns 10, 20, 30, and 40. Thus, even when the planar size of the coil component 100 is reduced, sufficient inductance can be obtained.

While the preferred embodiment of the present disclosure has been described, the present disclosure is not limited to the above embodiment, and various modifications may be made within the scope of the present disclosure, and all such modifications are included in the present disclosure.

For example, in the above embodiment, the bump conductors 131 and 132 are diagonally arranged, and the dummy bump conductors 133 and 134 are diagonally arranged; however, the positions of the bump conductors 131, 132 and dummy bump conductors 133, 134 are not particularly limited. Thus, the bump conductor 131 and dummy bump conductor 134 may be diagonally arranged by interchanging the positions of the bump conductor 132 and dummy bump conductor 134.

The technology according to the present disclosure includes the following configuration examples but not limited thereto.

A coil component according to one aspect of the present disclosure includes: an element body having a mounting surface including first to fourth corners; a plurality of conductor layers embedded in the element body so as to be stacked in a stacking direction perpendicular to the mounting surface; first and second bump conductors respectively exposed to the first and second corners of the mounting surface; first and second dummy bump conductors respectively exposed to the third and fourth corners of the mounting surface. The plurality of conductor layers each include a coil pattern, first and second connection patterns formed at positions respectively overlapping the first and second bump conductors as viewed in the stacking direction and respectively connected to the first and second bump conductors, and first and second dummy connection patterns formed at positions respectively overlapping the first and second dummy bump conductors as viewed in the stacking direction and respectively connected to the first and second dummy bump conductors. The coil patterns respectively included in the plurality of conductor layers are connected in series to constitute a coil conductor. One end of the coil conductor is connected to the first connection patterns respectively included in the plurality of conductor layers and the first bump conductor, and the other end of the coil conductor is connected to the second connection patterns respectively included in the plurality of conductor layers and the second bump conductor. The plurality of conductor layers include first and second conductor layers, and the outer peripheral end of the coil pattern included in the first conductor layer and the outer peripheral end of the coil pattern included in the second conductor layer are connected to each other through a first via hole. The first dummy connection pattern included in each of the first and second conductor layers has a cutout part, and at least a part of the outer peripheral end of the coil pattern included in each of the first and second conductor layers is disposed within the cutout part. With this configuration, the outer and inner diameters of the coil pattern can be increased.

In the above coil component, the first and second bump conductors may be diagonally arranged, and the first and second dummy bump conductors may be diagonally arranged. This can sufficiently ensure the outer and inner diameters of the coil pattern.

In the above coil component, the plurality of conductor layers may further include a third conductor layer, and the inner peripheral end of the coil pattern included in the second conductor layer and the inner peripheral end of the coil pattern included in the third conductor layer may be connected to each other through a second via hole. The element body may be shorter in the arrangement direction of the first bump conductor and first dummy bump conductor and longer in the arrangement direction of the first bump conductor and second dummy bump conductor, and the second via hole may be positioned closer in the longer direction to the second bump conductor and second dummy bump conductor than to the first bump conductor and first dummy bump conductor. This can further increase the outer and inner diameters of the coil pattern.

In the above coil component, the shortest distance between a third via hole connecting the first connection patterns respectively included in the plurality of conductor layers and the side surface of the element body perpendicular to the mounting surface thereof may be larger than the shortest distance between a fourth via hole connecting the first dummy connection patterns respectively included in the plurality of conductor layers and the side surface of the element body. This prevents the third via hole from being cut even when dicing displacement occurs, thus increasing product reliability.

The above coil component may further include a first conductive resin layer mounted on the mounting surface so as to connect the first bump conductor and the first dummy bump conductor and a second conductive resin layer mounted on the mounting surface so as to connect the second bump conductor and the second dummy bump conductor. This can obtain a terminal structure comparable to a four-terminal type coil component.

What is claimed is:

1. A coil component comprising:
an element body having a mounting surface including first, second, third, and fourth corners;
a plurality of conductor layers embedded in the element body so as to be stacked in a stacking direction perpendicular to the mounting surface;
first and second bump conductors respectively exposed to the first and second corners of the mounting surface; and
first and second dummy bump conductors respectively exposed to the third and fourth corners of the mounting surface,
wherein each of the plurality of conductor layers includes:
a coil pattern;
first and second connection patterns formed at positions respectively overlapping the first and second bump conductors as viewed in the stacking direction and respectively connected to the first and second bump conductors; and
first and second dummy connection patterns formed at positions respectively overlapping the first and second dummy bump conductors as viewed in the stacking direction and respectively connected to the first and second dummy bump conductors,
wherein the coil patterns respectively included in the plurality of conductor layers are connected in series to constitute a coil conductor having a first end and a second end,
wherein the first end of the coil conductor is connected to the first connection pattern included in each of the plurality of conductor layers and the first bump conductor,
wherein the second end of the coil conductor is connected to the second connection pattern included in each of the plurality of conductor layers and the second bump conductor,
wherein the plurality of conductor layers include first and second conductor layers,
wherein an outer peripheral end of the coil pattern included in the first conductor layer and an outer peripheral end of the coil pattern included in the second conductor layer are connected to each other through a first via hole,
wherein the first dummy connection pattern included in each of the first and second conductor layers has a cutout part, and
wherein at least a part of the outer peripheral end of the coil pattern included in each of the first and second conductor layers is disposed within the cutout part.

2. The coil component as claimed in claim 1,
wherein the first and second bump conductors are diagonally arranged, and
wherein the first and second dummy bump conductors are diagonally arranged.

3. The coil component as claimed in claim 1,
wherein the plurality of conductor layers further include a third conductor layer,
wherein an inner peripheral end of the coil pattern included in the second conductor layer and an inner peripheral end of the coil pattern included in the third conductor layer are connected to each other through a second via hole,
wherein the element body is shorter in an arrangement direction of the first bump conductor and first dummy bump conductor and longer in an arrangement direction of the first bump conductor and second dummy bump conductor, and
wherein the second via hole is positioned closer in a longer direction to the second bump conductor and second dummy bump conductor than to the first bump conductor and first dummy bump conductor.

4. The coil component as claimed in claim 1, wherein a shortest distance between a third via hole connecting the first connection patterns respectively included in the plurality of conductor layers and a side surface of the element body perpendicular to the mounting surface of the element body is larger than a shortest distance between a fourth via hole connecting the first dummy connection patterns respectively included in the plurality of conductor layers and the side surface of the element body.

5. The coil component as claimed in claim 1, further comprising:
a first conductive resin layer mounted on the mounting surface so as to connect the first bump conductor and the first dummy bump conductor; and
a second conductive resin layer mounted on the mounting surface so as to connect the second bump conductor and the second dummy bump conductor.
